(19) United States
(12) Patent Application Publication
(10) Pub. No.: US 2010/0194609 A1
(43) Pub. Date: Aug. 5, 2010

(54) Method and Device For Coding Data Words

(75) Inventors: Bernd Meyer, Munchen (DE); Marcus Schafheutle, Munchen (DE)

Correspondence Address: COHEN, PONTANI, LIEBERMAN & PAVANE LLP, 551 FIFTH AVENUE, SUITE 1210, NEW YORK, NY, 10176, US

(73) Assignee: Continental Automotive GmbH, Hannover (DE)

(21) Appl. No.: 12/677,410

(22) PCT Filed: Sep. 5, 2008
(86) PCT No.: PCT/EP2008/061732

§ 371 Date: Mar. 26, 2010

(30) Foreign Application Priority Data
Sep. 10, 2007 (DE) 10 2007 043 083.5

(51) Int. Cl. H03M 5/00

(52) U.S. Cl. 341/52

(57) ABSTRACT

The invention relates to a method for coding a data word having a prescribed quantity of arbitrary data symbols and a prescribed quantity of a reference data symbols, wherein a checksum with a prescribed quantity of cheek symbols is calculated for the data word and the quantity of arbitrary data symbols corresponds at least to the quantity of check symbols of the checksum.

### PRIORITY CLAIM

This is a U.S. national stage of application No. PCT/DE2008/001356, filed on Aug. 15, 2008, which claims Priority to the German Application Nos.: 10 2007 044 569.7, filed Sep. 10, 2007 and 10 2007 048 747.0, filed Oct. 8, 2007, the contents of all of which being incorporated herein by reference,

### BACKGROUND OF THE INVENTION

1. Field of the Invention

The present invention relates to a method and an apparatus for coding data words, as is necessary when storing or transmitting data, for example.

2. Related Art

Simple storage of data is usually not sufficient on account of errors that possibly arise during reading or writing. For this reason, the relevant data is normally coded and stored in coded form. In particular, what are known as error-correcting or error-recognizing codes are applied. This involves the application of appropriate algorithms to determine a code word and a checksum from a data word which is to be coded. Frequently, these are particularly security-relevant data that need to be stored in protected memories.

In a typical instance of application, the confidential memory content of an electronic storage medium that is protected by hardware measures against unauthorized reading by third parties is protected from memory errors such as bit flips or the like by an error-correcting code. Suitable access-protected memories are chip cards or security modules. In this context, the confidential data held in the protected memory is interpreted as code words of an error-correcting code and are extended by appropriate checksums for error recognition and/or correction. For reasons of memory space, it is desirable not to store the required checksums within the memory protected by hardware measures but rather to move them to a second, inexpensive memory which does not provide protection against unauthorized reading by third parties.

However, since the checksums calculated for error recognition and correction may be directly related to the confidential information within the code words, the checksum data also allow inferences regarding the information which is to be protected unless further protective measures are taken. In this case, although the checksums generally do not disclose the complete information contained in the code words, they can shed light on the stored data by subrelations, such as linear equations. If the main memory, that is to say the memory protected against access, contains data which is particularly worthy of protection, such as cryptographic keys, and if such data is located together with further known information in a common code word, it may also be possible to extract from the checksum the complete data that particularly needs to be protected, such as a complete key content, depending on the respective method used for error correction. If the checksum for the code word comprises s bytes, for example, then in the worst case s bytes of the key can also be calculated. Further measures for ensuring the confidentiality of such data is therefore required.

In the past, the use of encryption techniques has been proposed. In this case, a semantically secure encryption method has the property that a hacker is not able to distinguish between encryptions of data records of the same length, even if he has previously selected the data records to be encrypted. Encryptions therefore usually do not provide a hacker with any useful information about the encrypted data.

One possibility for also ensuring the confidentiality of the checksums for error recognition or correction is explicit encryption of the calculated checksums and storage in basically accessible memories or memory areas. That is to say that after the checksum generation for the data which is to be protected, the generated checksum is encrypted using a suitable cryptographic method and the checksum is decrypted again prior to any check on a code word.

However, such a practice gives rise to a series of drawbacks. The additional steps for encryption during the calculation or for decryption during the check on code words require an additionally necessary computation complexity, which is disadvantageous particularly when the code words need to be checked at regular intervals.

In addition, the relevant methods for encryption and decryption need to be implemented such that they do not impair the error-recognizing and correcting properties of the code used.

The methods for encryption and decryption must not allow any dependencies between various checksums to be inferred. By way of example, when using current ciphers for encrypting the checksums, it is necessary to use a randomized encryption method and to use new initialization vectors for every encryption. Furthermore, the keys used need to be stored in a protected memory, which necessitates an increased memory requirement.

Alternatively, it has been proposed to encrypt the data contents. This practice involves the data which need to be protected against errors being encrypted using an encryption method before the checksums are coded and calculated. The data does not necessarily need to be stored in encrypted form for this. It may be sufficient to temporarily encrypt the data just for calculating or checking code words, but otherwise to store it in plain text in the protected memory. However, a drawback in this context is that additional steps are required for the encryption during the calculation or for the decryption during the check on code words and mean additional computation complexity. Furthermore, the keys used need to be stored in the protected memory.

### SUMMARY OF THE INVENTION

It is an object of the invention to provide an improved method for coding data.

A method for coding a data word is provided, wherein the data word is constructed from a prescribed number of random data symbols and a prescribed number of user data symbols. A checksum with a prescribed number of check symbols is calculated for the data word. In this case, the number of random data symbols corresponds at least to the number of check symbols in the checksum.

As already explained at the outset, checksums arise particularly in error-recognition or error-correction methods. The invention does not involve a need for explicit encryption or decryption of the data. Merely the use of random data and the choice of the number of random data symbols based on a checksum calculation that allows the confidentiality of the data to be assured. Code or coding is subsequently understood to mean the generation of a code word and a checksum from a data word which is to be coded. The use of the mathematical properties, for example of the respective implemented error-recognizing or error-correcting code, implicitly achieves protection of the data which are to be protected. The insertion of random data that these random symbols are included in the calculation of the checksum, so that even in the knowledge of the checksum, which is stored in a non-write-protected memory area, for example, it is not possible to infer the contents of the user data. In this respect, the method is also not encryption, since the length of the calculated checksums is usually significantly less than the length of the data or user data to be protected and there is therefore generally no explicit relationship between calculated checksums and data to be protected.

The checksum is preferably calculated on the basis of a method for calculating checksums for error-correcting and/or error-recognizing codes. There are an array of codes or coding methods suitable for this, such as BCH (Bose-Chaudhuri-Hocquenghem), Reed-Solomon, CRC (Cyclic Redundancy Check) or Hamming codes. An appropriate function for calculating the checksum is preferably injective mapping of the random data symbols onto the check symbols. As a result, regardless of the specific choice of user data symbols, an entropy, which is conditional upon the random data, is retained even for the checksum.

By way of example, the random data symbols can be provided at prescribed places in the data word. In this case, the respective data symbols, such as bits or bytes, can be provided cohesively or else in individual regions of the respective data word.

In one variant of the method, a change in the user data symbols also involves the random data symbols being regenerated. This provides additional security.

Preferably, the user data symbols and the random data symbols are stored in an access-protected memory area. By way of example, an access-protected memory area can be provided by a chip card or special mechanical or electronic access mechanisms when reading from the secure memory area. By contrast, the check symbols can be stored in an unprotected memory area. Since it is not possible to infer the user data in the knowledge of the checksum, which is constructed from the check symbols, this saves more complex memory, for example a memory equipped with access protection, for storing the checksum. Preferably, the user data symbols are also stored in a cohesive memory area, and/or at least one adjoining memory area is used to store random data symbols. This means that the adjoining random data symbols can be used for the coding according to one embodiment of the invention. The user data symbols which form part of the data word which is to be coded may be present sequentially, for example, so that first of all a number of data symbols which are to be coded arise and then a number of random data symbols. However, the various data symbols may also arise and be used in a different order. In this way, the memory is split into blocks into which random data is written, so that simple coding and hence generation of a secure checksum can take place.

The invention also provides an apparatus for coding data words.

This apparatus has a control unit which is set up such that a method previous described as appropriate for coding a data word is performed.

By way of example, the apparatus can be designed on a software-implemented basis by virtue of suitable programming of a microprocessor.

Preferably, the apparatus is provided so as to have a random symbol generation unit which generates random data symbols. In addition, the apparatus may have a checksum calculation unit which calculates the checksum for a respective data word. In addition, in one particular embodiment, the apparatus has a memory device which stores random data symbols, check symbols or user data symbols in memory areas. In this case, an access-protected memory area is preferably provided for the random data symbols and the user data symbols.

Finally, according to one embodiment of the invention a computer program product that prompts the performance of an appropriate method for coding data words on a program-controlled computer device. By way of example, a suitable program-controlled computer device is a PC on which appropriate software is installed and which has interfaces for storing the coded data and checksums. By way of example, the computer program product can be implemented in the manner of a data storage medium, such as a USB stick, floppy disc, CD-ROM, DVD, or else may be implemented on a server device as a downloadable program file.

### BRIEF DESCRIPTION OF THE DRAWINGS

Further advantageous refinements of the invention and exemplary embodiments of the invention are described below. The text below provides a more detailed explanation of the invention using preferred embodiments with reference to the accompanying figures, in which:

FIG. 1 is a schematic illustration of a coded data word;

FIGS. 2A and 2B are coded data words in accordance with one embodiment of the coding method;

FIG. 3 is an exemplary flowchart of the method for coding data words;

FIG. 4 is a block diagram of a coding apparatus for data words; and

FIG. 5 is a plurality of data words to be coded.

### DETAILED DESCRIPTION OF THE DRAWINGS

In the figures, elements which are the same or have the same function have been provided with the same reference symbols unless stated otherwise.

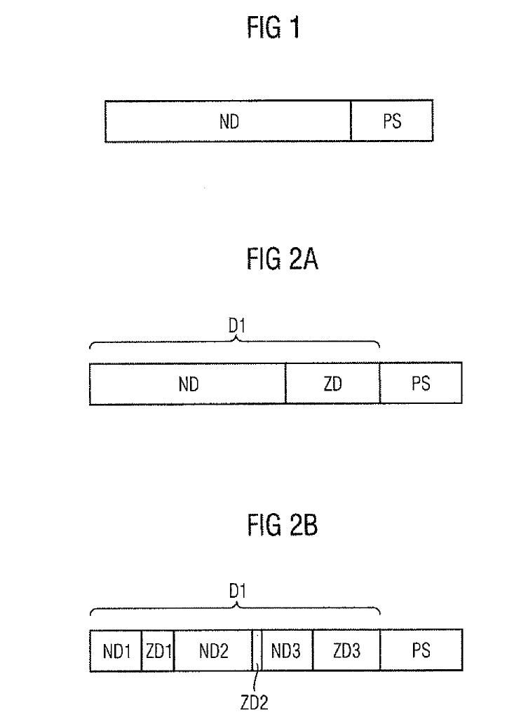

FIG. 1 is a coded data word with user data ND and a checksum PS. In this case, the user data comprise a prescribed number of data bits or data bytes, for example, and the checksum is indicated by a number of check bits, for example. The code word shown in FIG. 1 might have been generated using a BCH or RS code.

A code having the parameters (n, k, d) is subsequently assumed, n being the length of the code words, k being the length of the coded data words and d being a minimum distance between two code words. f denotes the mapping which attributes to a data word w=(w₀, . . . , wₖ₋₁) of length k the associated checksum s of length n-k for the associated code word, as shown schematically in FIG. 1.

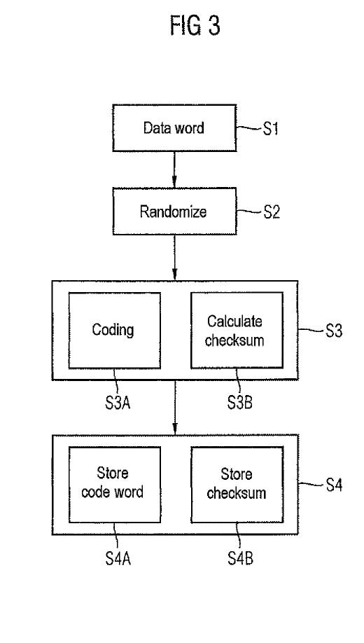

FIG. 2 are representations of data words or code words which are to be coded in order to illustrate a variant of the proposed method for coding data words. In FIG. 2A, a data word D1 is first of all provided which has a prescribed number of user data symbols, such as data bits ND. In addition, random data bits ZD are provided in the data word D1 It is assumed that a coding method is used which attributes a checksum PS of length n-k symbols to the associated code word.

FIG. 2B likewise shows a data word D1 with the associated checksum PS and the check symbols but where the user data ND1, ND2, ND3 are not cohesive, but rather are split into subregions. In between, there are places in the data word D1 which are provided with the random data bits or random data symbols ZD1, ZD2, ZD3. In this case, the number of random data symbols corresponds to the number of symbols needed for the checksum PS. It is also possible to use more random symbols than check symbols.

FIG. 3 is an exemplary flowchart for coding data words. In this case, the starting point is first of all a data word in step S1.

In one embodiment of the coding method, n-k positions of data symbols 0≦i₁< . . . <iₙ₋ₖ<k in a data word D are selected for the code used and, prior to the calculation of the checksum s, have random values or random symbols written to them (step S2). The data word D′ obtained in this manner is stored in the protected memory of the relevant storage medium, and the associated calculated checksum S with corresponding checksum symbols PS is stored in the unprotected memory.

In line with the flowchart in FIG. 3, the checksum calculation is performed in step S3. In this case, as an optional substep S3A, yet further coding is specified for the user data symbols—to which random data symbols have been added—of the data word which is to be coded. The checksum calculation is performed with the step denoted S3B in line with the respective method used. In this case, it is possible to use a method based on the Reed-Solomon code (RS code). Reed-Solomon codes are cyclic codes and form a subclass of BCH codes. By way of example, the error correction in audio CDs is formed on the basis of a Reed-Solomon code. RS codes are also used for digital mobile radio or digital video broadcasting. The checksum can then be used to recover respective bits or bytes which have been damaged during the transmission or during the storage. It goes without saying that it is also possible to use other known coding methods.

The storage step S4 shows that firstly the code word is stored in substep S4A and secondly the checksum symbols are stored as a checksum in step S4B. In this case, the checksum symbols are preferably stored in a memory area without further protection. By contrast, the security-sensitive code words, which, line with the method, also have randomized, that is to say random, symbols, however, are stored in an especially protected memory or memory area. By way of example, the checksum can be stored in an ordinary memory card, such as a flash memory, and the user data and random data can be stored in a special chip card.

By way of example, the method can be used when security-relevant data need to be stored in data words. By way of example, this is the case when electronic tachographs are used. In this case, the security-relevant data are deemed to be the respective information from the tachograph, which must not be manipulated. The collected data from a driver can in this case be stored on a personal driver card in the form of a chip card with a protected memory. By contrast, the checksums, which are likewise obtained during the storage and associated coding, can be stored in a less sensitive or protected memory device.

The proposed method for coding data words makes use of the property of the function f, which, as a result of the underlying method, is intended for coding or for generating the checksum. If the function f for calculating the checksum S=f(D′) has, in particular, the property that it is injective mapping with n-k unknowns at the positions iₙ₋ₖ for arbitrary but firmly chosen combinations of symbols at the 2k-n positions other than i₁, . . . , iₙ₋ₖ, the calculated checksum S does not contain any information about the coded data word D′ which can be used by a potential hacker.

As a result of the n-k positions i₁, . . . , iₙ₋ₖ in the data word D′ being filled with random symbols, the entropy of the source of the data words generated in this manner is n-k symbols. The injectivity of the function f with undefined items at the n-k positions i₁, . . . , iₙ₋ₖ ensures that this entropy is retained when the checksum S is calculated. This is regardless of the specific symbols at the remaining 2k-n positions. In this context, the calculated checksum S has no information about the symbols at the remaining positions of the code word D′ in an information theory sense.

The random symbols at the n-k positions i₁, . . . , iₙ₋ₖ cover the information about the remaining 2k-n data symbols in the checksum.

To protect memory areas that contain data which is particularly worthy of protection, such as cryptographic keys in the system, against loss of confidentiality as a result of removed checksums, the respective n-k positions i₁, . . . , iₙ₋ₖ in each block are reserved in blocks of length k prior to calculation of the checksums and have random symbols written to them. For every change in the data contents of the blocks, the symbols at these positions should be overwritten with random symbols again prior to the calculation of the checksums.

The practice described ensures the confidentiality of the data without requiring explicit encryption or decryption. Only through the use of certain mathematical properties of the implemented error-recognizing or correcting codes is protection of the confidentiality of the data which is to be protected implicitly achieved. It is merely necessary to execute the normal algorithmic steps for calculating or checking code words. The protection of the confidentiality of the checksums is achieved implicitly. This allows the method described to be implemented very efficiently.

To achieve security in terms of information theory in the method according to the invention, it is sufficient if the entropy of the inserted random symbols is greater than or equal to the entropy of the checksums calculated thereby. This achieves a higher level of security than in the case of semantic encryption methods.

The only requirement of the method is that selected areas preferably have random values written to them before the checksums are calculated. This can be carried out when initializing an appliance equipped with the coding method, for example when cryptographic keys which are to be protected are installed. In particular, there is no need for additional program parts for an encryption or decryption function or case distinctions for handling the data which is to be protected. No upstream or downstream computation operations are required, nor do the coding and decoding routines need to be modified.

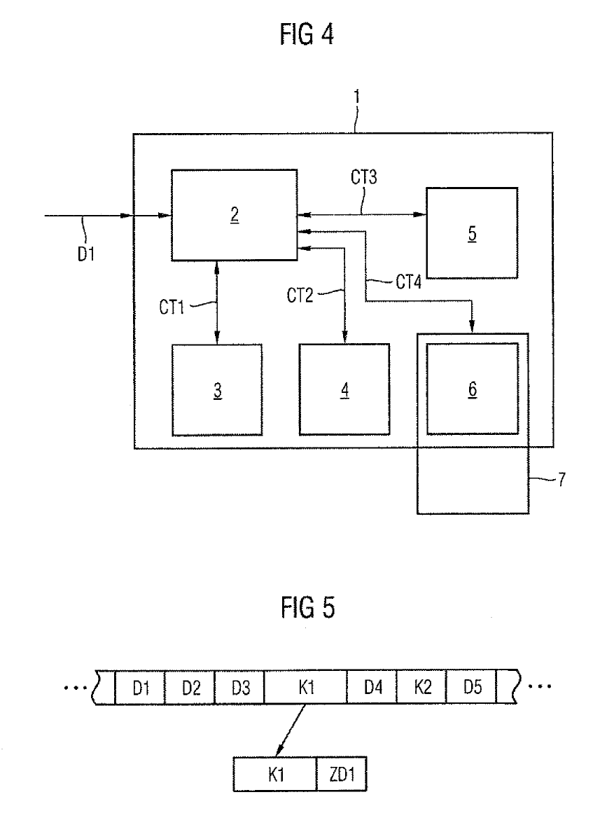

FIG. 4 is a block diagram of an exemplary apparatus which is suitable for performing the coding method. In this case, the apparatus 1 has a control unit 2 which receives the respective data word D1 on an external interface. Furthermore, the apparatus for coding 1 has a checksum generation unit 3, a random symbol generation unit 4 and memory devices 5 and 6. The control unit 2 is coupled by a suitable data bus to the checksum calculation unit 3, the random symbol generation unit 4 and memory devices 5, 6.

The control unit 2 coordinates the respective generation of the checksums and random symbols, and also the storage in the various memory areas. In this case, the memory device 5 is in the form of a conventional, non-access-protected memory, for example. The second memory 6 may be in the form of part of a chip card, for example, which is shown by reference symbol 7. The chip card 7, which has the access-protected memory 6, can be introduced into a drawer in the coding apparatus

The coding apparatus 1 with its respective elements 2, 3, 4, 5, 6 may also be of computer-implemented design, where the individual blocks 2, 3, 4, 5, 6 are regarded as respective program parts. During operation of the coding apparatus 1, the method steps described previously are executed in coordinated fashion by the control unit 2, for example.

As a result, the memory areas 5 and 6 contain coded data, the confidentiality of which can be ensured.

To protect a larger memory area against errors, the respective memory area is usually split into sections having a selected length, and the associated checksum is calculated and stored for each section. If a section contains data contents, the confidentiality of which requires particular protection, such as a cryptographic key, then it is sufficient for the purpose of implementing the method according to the invention if a memory area with random data is inserted before and/or after the data whose confidentiality needs to be protected. This is illustrated in FIG. 5.

In this case, data words D1-D3, K1, D4, K2 and D5 are shown. By way of example, the data words K1 and K2 have particularly security-relevant cryptographic keys. The data words shown by way of example in FIG. 5 can also be regarded as data areas which respectively contain a plurality of data words. In this case, the areas K1 and K2 should be regarded as data requiring particular protection.

FIG. 5 illustrates the addition of random data ZD1 by way of example using the area K1 which needs to be protected. Addition of the random data symbols ZD1 results in a code word and an appropriate checksum during otherwise ordinary coding, for example using a BCH, CRC or RS code. In the coding process, the random data symbols are also understood as a data word which needs to be coded. On the basis of the added random data or the randomization in portions of the data word which is to be coded, the checksum and the resultant coded user data can be stored separately, and even in the knowledge of the checksum there is no danger of the confidentiality of the coded data being breached. Self-evidently, a plurality of areas with additional randomized data can also be provided. To protect the area K2, said area needs to be extended in appropriate fashion by adding random data symbols.

If the area requiring particular protection overlaps a plurality of code words, memory areas with random data of suitable length need to be inserted into all the code words affected.

Although the present invention has been explained in more detail with reference to preferred embodiments, it is not limited thereto but rather can be modified in a wide variety of ways. In particular, the cited coding methods, which generate checksums, should be understood to be merely exemplary and not conclusive. The cited examples of protected and unprotected memory areas to be used are also not conclusive citations.

Thus, while there have shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-15. (canceled)

16. A method for coding a data word comprising:
receiving the data word comprising a prescribed number of random data symbols and a prescribed number of user data symbols; and
calculating a checksum with a prescribed number of check symbols for the data word,
wherein the number of random data symbols at least corresponds to the number of check symbols in the checksum.

17. The method as claimed in claim 16, wherein the checksum is calculated based at least in part on calculating checksums for at least one of error-correcting and error-recognizing codes.

18. The method as claimed in claim 16, wherein a function is used for calculating the checksum which, for any arbitrarily prescribed use of the user data symbols, is injective mapping of the random data symbols onto the check symbols.

19. The method as claimed in claim 16, wherein prescribed places in the data word have the random data symbols written to them.

20. The method as claimed in claim 16, wherein a change in the user data symbols comprises regenerating the random data symbols.

21. The method as claimed in claim 16, further comprising storing the user data symbols and random data symbols in an access-protected memory area.

22. The method as claimed in claim 16, further comprising storing the check symbols in an unprotected memory area.

23. The method as claimed in claim 16, wherein at least one of the check symbols, the user data symbols, and the random data symbols are one of data bits and data bytes.

24. The method as claimed in claim 16, wherein the user data symbols are stored in a cohesive memory area, and at least one adjoining memory area is used to store random data symbols.

25. An apparatus for coding data words with a control unit configured to:
receive a data word having a prescribed number of random data symbols and a prescribed number of user data symbols; and
calculate a checksum with a prescribed number of check symbols for the data word,
wherein the number of random data symbols at least corresponds to the number of check symbols in the checksum.

26. The apparatus as claimed in claim 25, further comprising a random symbol generation unit configured to generate the random data symbols.

27. The apparatus as claimed in claim 25, further comprising a checksum calculation unit configured to calculate the checksum for a respective data word.

28. The apparatus as claimed in claim 25, further comprising a memory device configured to store at least one of the random data symbols, the check symbols and the user data symbols.

29. The apparatus as claimed in claim 25, further comprising an access-protected memory area configured to store at least one of the random data symbols and the user data symbols.

30. A computer program product which prompts performance of a method on a program-controlled computer device comprising a processor, the method comprising:
receiving a data word having a prescribed number of random data symbols and a prescribed number of user data symbols; and
calculating a checksum with a prescribed number of check symbols for the data word, wherein the number of random data symbols at least corresponds to the number of check symbols in the checksum.

31. The method as claimed in claim 17, wherein the checksum is calculated based at least in part on at least one of a BCH, Reed-Solomon, CRC or Hamming code.

32. The method as claimed in claim 21, further comprising storing the check symbols in an unprotected memory area.

33. The apparatus as claimed in claim 27, further comprising a memory device configured to store at least one of the random data symbols, the check symbols and the user data symbols.

34. The apparatus as claimed in claim 33, further comprising an access-protected memory area configured to store at least one of the random data symbols and the user data symbols.
